(19) United States
(12) Patent Application Publication
(10) Pub. No.: US 2020/0211667 A1
(43) Pub. Date: Jul. 2, 2020

(54) Efuse Programming Unit, Efuse Circuit and Programming Process Thereof

(71) Applicant: Shanghai Huali Microelectronics Corporation, Shanghai (CN)

(72) Inventors: Ying Yan, Shanghai (CN); Jianming Jin, Shanghai (CN); Zheng Gong, Shanghai (CN)

(73) Assignee: Shanghai Huali Microelectronics Corporation, Shanghai (CN)

(21) Appl. No.: 16/684,989

(22) Filed: Nov. 15, 2019

(30) Foreign Application Priority Data
Dec. 29, 2018 (CN) 201811632076.0

(51) Int. Cl. G11C 17/18; G11C 17/16

(52) U.S. Cl. CPC G11C 17/18; G11C 17/16

(57) ABSTRACT

Embodiments described herein relate to an efuse programming unit, an efuse circuit and a programming process thereof. The efuse circuit comprises an efuse programming unit comprising an efuse component and an anti-efuse programming transistor, the anti-efuse programming transistor being connected in parallel with the efuse component, wherein the anti-efuse programming transistor is an electrically programmable device, presents a high-resistance state before programming and presents a low-resistance state after programming, and the efuse component is an electrically programmable device, presents a low-resistance state before programming and presents a high-resistance after programming; and a programming control device connected in series with the efuse programming unit.

### CROSS REFERENCE TO RELATED APPLICATIONS

The present application claims priority to and the benefit of Chinese Patent Application No. 201811632076.0 filed on Dec. 29, 2018, the disclosure of which is incorporated herein by reference in its entirety as part of the present application.

### BACKGROUND OF THE INVENTION

Embodiments described herein relate to a semiconductor integrated circuit, in particular to an efuse programming unit, an efuse circuit and a programming process thereof

With the development of semiconductor industry, the requirements for high speed, high precision and high stability of electronic devices are becoming stricter and stricter. In semiconductor integrated circuits, efuse circuit is one of commonly used structures in one-time programmable (OTP) memories, and in the efuse circuit, according to the electron migration (EM) characteristics, programming is performed on a chip by adopting an efuse structure. As a semiconductor device, the efuse circuit has been widely used in communication devices, computers and other processors and requirements on its performance are also getting higher and higher.

### BRIEF SUMMARY OF THE INVENTION

According to embodiments described herein there is provided an efuse circuit. The efuse circuit comprises an efuse programming unit comprising an efuse component and an anti-efuse programming transistor, the anti-efuse programming transistor being connected in parallel with the efuse component, wherein the anti-efuse programming transistor is an electrically programmable device, presents a high-resistance state before programming and presents a low-resistance state after programming, and the efuse component is an electrically programmable device, presents a low-resistance state before programming and presents a high-resistance after programming; and a programming control device connected in series with the efuse programming unit.

According to embodiments described herein there is provided a programming process of the efuse circuit, the programming process comprises the follows: before programming: the programming control device is not conducted, the efuse programming unit is in a pre state, the efuse component presents a low-resistance state at the pre state, the gate Ga-source Gs of the anti-efuse programming transistor presents a high-resistance state at the pre state, the parallel structure comprising the efuse component and the anti-efuse programming transistor presents a low-resistance state before programming, and its logical state is defined as “0”; a first-time programming operation is performed that the programming control device receives a high-level control signal and is conducted, when the working voltage of the efuse programming unit is set to Vp and the programming time is Tp, the efuse component breaks and presents a high-resistance state after programming, the state of the anti-efuse programming transistor remains unchanged and is still a high-resistance state, the parallel structure comprising the efuse component and the anti-efuse programming transistor presents a high-resistance state after first-time programming, and its logical state is defined as “1”; and a second-time programming operation is performed that the programming control device receives a control signal and is conducted, when the working voltage of the efuse programming unit is set to Va and the programming time is Ta, the gate-oxide of anti-efuse programming transistor breaks down and presents a low-resistance state after programming, the efuse component still presents a high-resistance state after first-time programming, the parallel structure comprising the efuse component and the anti-efuse programming transistor presents a low-resistance state after second-time programming, and its logical state is defined as “0”.

According to embodiments described herein there is provided a efuse programming unit, the efuse programming unit comprises an efuse component and an anti-efuse programming transistor, the anti-efuse programming transistor being connected in parallel with the efuse component, wherein the anti-efuse programming transistor is an electrically programmable device, presents a high-resistance state before programming and presents a low-resistance state after programming; and the efuse component is an electrically programmable device, presents a low-resistance state before programming and presents a high-resistance state after programming.

### BRIEF DESCRIPTION OF THE SEVERAL VIEWS OF THE DRAWINGS

FIG. 1 is a schematic diagram of an efuse circuit.

FIG. 2 is a structural schematic diagram of an efuse circuit according to one embodiment.

FIG. 3 is a schematic diagram of a programming process of the efuse circuit illustrated in FIG. 2 according to one embodiment.

FIG. 4 is a schematic diagram of an efuse circuit according to one embodiment.

Description of reference signs of main components in the drawings:

100. programming control device; 120. efuse programming unit; 102. drain; 104. source; 122. first electrode; 121. efuse component; 124. second electrode; 123. anti-efuse programming transistor

### DETAILED DESCRIPTION OF THE INVENTION

The technical solution in the present disclosure will be clearly and completely described below with reference to the drawings. Obviously, the described embodiments are part of the embodiments of the present disclosure instead of all of the embodiments. Based on the embodiments of the present disclosure, all other embodiments acquired by one skilled in the art without contributing any inventive labor shall also fall within the scope of protection of the present disclosure.

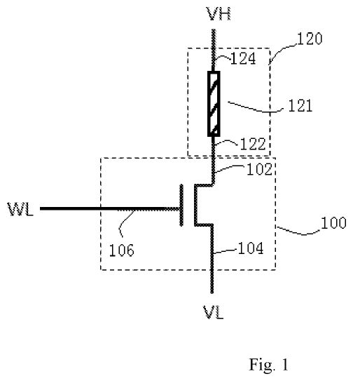

Please refer to FIG. 1. FIG. 1 is a schematic diagram of an efuse circuit. As illustrated in FIG. 1, the efuse circuit comprises a programming control device 100 and an efuse programming unit 120. As illustrated in FIG. 1, the efuse programming unit 120 comprises an efuse component 121, a first electrode 122 and a second electrode 124. The programming control device 100 is a controlled switching device and comprises a drain 102, a source 104 and a gate 106. In one embodiment, the controlled switching device is an N-type field effect transistor (N-MOSFET).

In the efuse circuit illustrated in FIG. 1, the drain 102 of the programming control device 100 is connected with the first electrode 122 of the efuse programming unit 120 to form a serial structure of the programming control device 100 and the efuse programming unit 120. The source 104 of the programming control device 100 configured to form a low-level end VL of the efuse circuit, the second electrode 124 of the efuse programming unit 120 configured to form a high-level end VH of the efuse circuit, and the gate 106 of the programming control device 100 configured to receive a control signal to form a control end WL of the efuse circuit. The efuse component 121 is an electrically programmable device. By applying a control signal to the gate 106 and applying a voltage between the second electrode 124 and the source 104, the intensity of current flowing through the efuse component 121 can be changed, resulting in the electron migration in the efuse wire of the efuse component 121, and making the efuse component 121 (i.e., the efuse programming unit 120 illustrated in FIG. 1) be in a low-resistance state before programming or a high-resistance state after programming, and thus the efuse component 121 has been widely used. Generally, the logic state of the low-resistance state before programming is defined as “0”; the logic state of the high-resistance state after programming is defined as “1”.

However, the efuse circuit illustrated in FIG. 1 can only be programmed for one time, that is, from the low-resistance state before programming to the high-resistance state after programming, which limits the on-site use conditions for a user and product production test capability, and causes poor redundancy.

In one embodiment, an efuse circuit is provided to improve the applicability of the efuse circuit. By improving the structure of the conventional efuse circuit, the efuse circuit according to one embodiment of the present disclosure has second correction ability, i.e., the previous programming result can be reprogrammed and repaired.

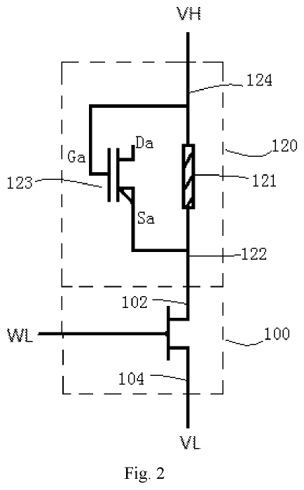

Please refer to FIG. 2. FIG. 2 is a structural schematic diagram of an efuse circuit according to one embodiment. As illustrated in FIG. 2, the efuse circuit also comprises a serial structure comprising a programming control device 100 and an efuse programming unit 120, wherein the efuse programming unit 120 comprises an efuse component 121 and an anti-efuse programming transistor 123, the anti-efuse programming transistor 123 is connected in parallel with the efuse component 121, the anti-efuse programming transistor 123 is an electrically programmable device, presents a high-resistance state before programming and presents a low-resistance state after programming, i.e., the logic state before programming is “1” and the logic state after programming is “0”.

For example, please refer to FIG. 2 again. As illustrated in FIG. 2, the anti-efuse programming transistor 123 comprises a gate Ga, a drain Da and a source Sa, wherein the gate Ga is connected with one end of the efuse component 121 to form the second electrode 124 of the efuse programming unit 120, and the source Sa is connected with the other end of the efuse component 121 to form the first electrode 122 of the efuse programming unit 120, thereby forming a parallel structure of the anti-efuse programming transistor 123 and the efuse component 121. Further, as illustrated in FIG. 2, the drain Da of the anti-efuse programming transistor 123 is open. Please refer to FIG. 2 again. The structure of the programming control device 100 illustrated in FIG. 2 is the same as that of the programming control device 100 illustrated in FIG. 1. As the same as that in FIG. 1, the drain 102 of the programming control device 100 is connected with the first electrode 122 of the efuse programming unit 120, the source 104 of the programming control device 100 configured to form a low-voltage end VL of the efuse circuit, the second electrode 124 of the efuse programming unit 120 configured to form a high-voltage end VH of the efuse circuit, and the gate 106 of the programming control device 100 configured to receive a control signal to form a control end WL of the efuse circuit, thereby forming a serial structure of the programming control device 100 and the efuse programming unit 120.

Further for example, in one embodiment, the gate Ga of the anti-efuse programming transistor 123 is directly connected with one end of the efuse component 121 to form the second electrode 124 of the efuse programming unit 120. In one embodiment, the source Sa of the anti-efuse programming transistor 123 is directly connected with the other end of the efuse component 121 to form the first electrode 122 of the efuse programming unit 120.

Further for example, in one embodiment, the breakdown voltage of the anti-efuse programming transistor 123 is Va, and the efuse component 121 corresponds to working current Ip under voltage Vp, and the efuse component 121 breaks when the programming time is Tp, wherein the voltage Vp is smaller than the breakdown voltage Va. In one embodiment, the difference between Va and Vp is greater than 3V.

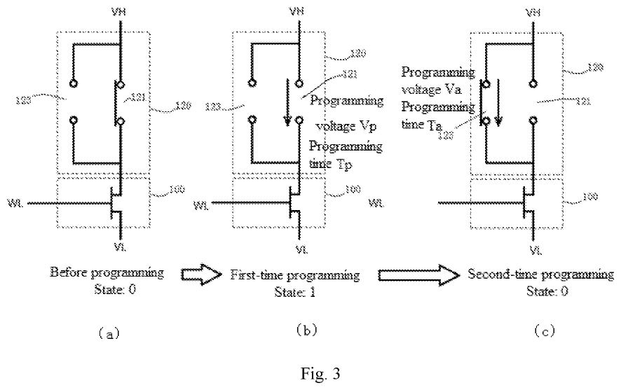

As follows, the working process of the efuse circuit illustrated in FIG. 2 will be described in detail. Specifically, please refer to FIG. 3. FIG. 3 is a schematic diagram of a programming process of the efuse circuit illustrated in FIG. 2 according to one embodiment.

As illustrated in FIG. 3a, before programming: the programming control device 100 is not conducted, the efuse programming unit 120 is in a pre state, the efuse component 121 is in a low-resistance state at the pre state, and the gate Ga-source Gs of the anti-efuse programming transistor 123 is in a high-resistance state at the pre state, the parallel structure (i.e., the efuse programming unit 120) comprising the efuse component 121 and the anti-efuse programming transistor 123 presents a low-resistance state before programming, and its logical state is defined as “0”.

As illustrated in FIG. 3b, a first-time programming (normal programming) operation is performed: the programming control device 100 receives a high-level control signal and is conducted, when the working voltage of the efuse programming unit 120 is set to Vp (current Ip) and the programming time is Tp, the efuse component 121 breaks and presents a high-resistance state after programming, the state of the anti-efuse programming transistor 123 remains unchanged and is still a high-resistance state, the parallel structure (i.e., the efuse programming unit 120) comprising the efuse component 121 and the anti-efuse programming transistor 123 presents a high-resistance state after first-time programming, and its logical state is defined as “1”.

Since the breakdown voltage Va of the anti-efuse programming transistor 123 is relatively high, when the working voltage is set to Vp, the efuse component 121 breaks and the anti-efuse programming transistor 123 remains unchanged.

As illustrated in FIG. 3c, a second-time programming operation is performed: the programming control device 100 receives a high-level control signal and is conducted, when the working voltage of the efuse programming unit 120 is set to Va and the programming time is Ta, the gate-oxide of anti-efuse programming transistor 123 breaks down and presents a low-resistance state after programming, the efuse component 121 still presents a high-resistance state after first-time programming, the parallel structure (i.e., the efuse programming unit 120) comprising the efuse component 121 and the anti-efuse programming transistor 123 presents a low-resistance state after second-time programming, and its logical state is defined as “0”.

As mentioned above, according to one embodiment, if the bit value of the efuse programming unit 120 after first-time programming needs to be modified, i.e., the state needs to be corrected from the logical state “1” to the logical state “0”, the efuse programming unit 120 can be continuously subjected to a second-time programming operation. i.e., the efuse circuit according to one embodiment of the present disclosure has another reprogramming opportunity after normal programming. As illustrated in FIG. 3, before programming, the efuse programming unit 120 is in a state of “0”; after first-time programming, the efuse programming unit 120 is in a state of “1”; through second-time programming, the efuse programming unit 120 can be corrected back to “0”. However, in the prior art, in order to correct a wrong programming result of an efuse programming unit, redundant bits are mainly added. That is to say, the redundant bit area is additionally configured, and by programming the redundant bits, the location information and the actual value of the bits where the error occurs are recorded. When users encounter bits with read-out errors, the system reads out redundant values automatically. One embodiment of the present disclosure has a new way. Instead of using traditional redundant bits to correct errors occurring in the programming process of the efuse programming unit, one embodiment of the present disclosure directly adopts a two-time programming operation to correct errors. The circuit and layout designs can be greatly simplified, and the use flexibility and controllability for users are better, and the programming reliability is higher according to one embodiment.

In one embodiment, an efuse programming unit 120, as described above, is further provided, comprising a parallel structure comprising an efuse component 121 and an anti-efuse programming transistor 123, so that the efuse circuit comprising the efuse programming unit 120 connected with a programmable controller device 100 has a second-time correction capability according to one embodiment.

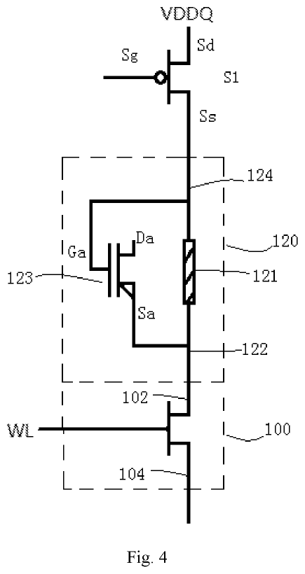

In one embodiment, a main control switch S1 is further provided to control the efuse circuit of the present disclosure to be in a working state or not. Specifically, please refer to FIG. 4. FIG. 4 is a schematic diagram of an efuse circuit according to one embodiment. As shown in FIG. 4, the circuit comprises a main control switch S1, which comprises a gate Sg, a source Ss and a drain Sd. The main control switch S1 and the efuse circuit illustrated in FIG. 2 configured to form a serial structure to control the efuse circuit to be in a working state or not. Further for example, as illustrated in FIG. 4, the source Ss of the main control switch S1 is connected with the second electrode 124 of the efuse programming unit 120, and the drain Sd of the main control switch Si is connected with a voltage end to form a serial structure of the main control switch Si and the efuse circuit.

Finally, it should be noted that the above embodiments are used only for describing the technical solution of the present disclosure instead of limiting the present disclosure. Although the present disclosure is described in detail with reference to the above embodiments, one skilled in the art should understand that the technical solution recorded in the above embodiments can also be modified, or some or all of technical features thereof are replaced equally; and these modifications or replacements do not cause the essence of the corresponding technical solution to be departed from the scope of the technical solution of the embodiments of the present disclosure.

What is claimed is:

1. An efuse circuit comprising:
an efuse programming unit configured to comprise an efuse component and an anti-efuse programming transistor, the anti-efuse programming transistor being connected in parallel with the efuse component, wherein the anti-efuse programming transistor is an electrically programmable device, presents a high-resistance state before programming and presents a low-resistance state after programming; the efuse component is an electrically programmable device, presents a low-resistance state before programming and presents a high-resistance after programming; and
a programming control device connected in series with the efuse programming unit.

2. The efuse circuit according to claim 1, wherein the anti-efuse programming transistor comprises a gate Ga, a drain Da and a source Sa, wherein the gate Ga is connected with one end of the efuse component to form a second electrode of the efuse programming unit, the source Sa is connected with the other end of the efuse component to form a first electrode of the efuse programming unit, and the drain Da of the anti-efuse programming transistor is open.

3. The efuse circuit according to claim 2, wherein the programming control device is a controlled switching device and comprises a drain, a source and a gate, the drain of the programming control device is connected with the first electrode of the efuse programming unit, the source of the programming control device configured to form a low-voltage end VL of the efuse circuit, the second electrode of the efuse programming unit configured to form a high-voltage end VH of the efuse circuit, and the gate of the programming control device configured to receive a control signal to form a control end of the efuse circuit.

4. The efuse circuit according to claim 2, wherein the gate Ga of the anti-efuse programming transistor is directly connected with one end of the efuse component to form the second electrode of the efuse programming unit, and the source Sa of the anti-efuse programming transistor is directly connected with the other end of the efuse component to form the first electrode of the efuse programming unit.

5. The efuse circuit according to claim 1, wherein the breakdown voltage of the anti-efuse programming transistor is Va, the efuse component corresponds to working current Ip under voltage Vp, and the efuse component breaks when programming time is Tp, wherein the voltage Vp is smaller than the breakdown voltage Va.

6. The efuse circuit according to claim 3, wherein the controlled switching device is an N-type field effect transistor.

7. The efuse circuit according to claim 5, wherein the difference between Va and Vp is greater than 3V.

8. The efuse circuit according to claim 2, wherein the efuse circuit further comprises a main control switch, and the main control switch S1 comprises a gate Sg, a source Ss and a drain Sd, wherein the source Ss of the main control switch is connected with the second electrode of the efuse programming unit, and the drain Sd of the main control switch Si is connected with a voltage end.

9. A programming process of the efuse circuit according to claim 1, wherein the programming process comprises:
before programming: the programming control device is not conducted, the efuse programming unit is in a pre state, the efuse component presents a low-resistance state at the pre state, the gate Ga-source Gs of the anti-efuse programming transistor presents a high-resistance state at the pre state, the parallel structure comprising the efuse component and the anti-efuse programming transistor presents a low-resistance state before programming, and its logical state is defined as “0”;
a first-time programming operation: the programming control device receives a high-level control signal and is conducted, when the working voltage of the efuse programming unit is set to Vp and the programming time is Tp, the efuse component breaks and presents a high-resistance state after programming, the state of the anti-efuse programming transistor remains unchanged and is still a high-resistance state, the parallel structure comprising the efuse component and the anti-efuse programming transistor presents a high-resistance state after first-time programming, and its logical state is defined as “1”; and
a second-time programming operation: the programming control device receives a high-level control signal and is conducted, when the working voltage of the efuse programming unit is set to Va and the programming time is Ta, the gate-oxide of anti-efuse programming transistor breaks down and presents a low-resistance state after programming, the efuse component still presents a high-resistance state after first-time programming, the parallel structure comprising the efuse component and the anti-efuse programming transistor presents a low-resistance state after second-time programming, and its logical state is defined as “0”.

10. The programming process according to claim 9, wherein the voltage Vp is smaller than the voltage Va.

11. The programming process according to claim 10, wherein the difference between Va and Vp is greater than 3V.

12. An efuse programming unit comprising:
an efuse component and an anti-efuse programming transistor, the anti-efuse programming transistor being connected in parallel with the efuse component, wherein the anti-efuse programming transistor is an electrically programmable device, presents a high-resistance state before programming and presents a low-resistance state after programming; and the efuse component is an electrically programmable device, presents a low-resistance state before programming and presents a high-resistance state after programming.

13. The efuse programming unit according to claim 12, wherein the anti-efuse programming transistor comprises a gate Ga, a drain Da and a source Sa, wherein the gate Ga is connected with one end of the efuse component to form a second electrode of the efuse programming unit, the source Sa is connected with the other end of the efuse component to form a first electrode of the efuse programming unit, and the drain Da of the anti-efuse programming transistor is open.

14. The efuse programming unit according to claim 13, wherein the gate Ga of the anti-efuse programming transistor is directly connected with one end of the efuse component to form the second electrode of the efuse programming unit, and the source Sa of the anti-efuse programming transistor is directly connected with the other end of the efuse component to form the first electrode of the efuse programming unit.

15. The efuse programming unit according to claim 12, wherein the breakdown voltage of the anti-efuse programming transistor is Va, the efuse component corresponds to working current Ip under voltage Vp, and the efuse component breaks when programming time is Tp, wherein the voltage Vp is smaller than the breakdown voltage Va.

16. The efuse programming unit according to claim 15, wherein the difference between Va and Vp is greater than 3V.
